(19) United States
(12) Patent Application Publication
(10) Pub. No.: US 2025/0023530 A1
(43) Pub. Date: Jan. 16, 2025

(54) RECEIVER CIRCUIT, A SEMICONDUCTOR APPARATUS AND A SEMICONDUCTOR SYSTEM USING THE SAME

(71) Applicant: SK hynix Inc., Icheon-si Gyeonggi-do (KR)

(72) Inventors: Jun Seo JANG, Icheon-si Gyeonggi-do (KR); Bon Kwang KOO, Icheon-si Gyeonggi-do (KR); Beom Kyu SEO, Icheon-si Gyeonggi-do (KR); Soon Sung AN, Icheon-si Gyeonggi-do (KR); Sung Hwa OK, Icheon-si Gyeonggi-do (KR); Eun Ji CHOI, Icheon-si Gyeonggi-do (KR); Jae Hyeong HONG, Icheon-si Gyeonggi-do (KR)

(73) Assignee: SK hynix Inc., Icheon-si Gyeonggi-do (KR)

(21) Appl. No.: 18/537,560

(22) Filed: Dec. 12, 2023

(30) Foreign Application Priority Data
Jul. 10, 2023 (KR) 10-2023-0089236

(51) Int. Cl. H03F 3/45; H03F 3/68

(52) U.S. Cl. CPC H03F 3/45183; H03F 3/68

(57) ABSTRACT

A receiver circuit includes a first amplification stage and a second amplification stage. The first amplification stage is configured to generate a first output signal by differentially amplifying an input signal pair. The second amplification stage is configured to generate a second output signal by amplifying the first output signal. The receiver circuit is configured to deactivate the second amplification stage and then deactivate the first amplification stage.

### CROSS-REFERENCES TO RELATED APPLICATION

The present application claims priority under 35 U.S.C. § 119 (a) to Korean application number 10-2023-0089236, filed on Jul. 10, 2023, in the Korean Intellectual Property Office, which is incorporated herein by reference in its entirety.

### BACKGROUND

### 1. Technical Field

The present disclosure relates to an integrated circuit technology, and more particularly, to a receiver circuit, a semiconductor apparatus and a semiconductor system using the same.

### 2. Related Art

Electronic devices may include many electronic components, and among the electronic devices, a computer system may include many semiconductor apparatuses made of semiconductor devices. The semiconductor apparatuses constituting the computer system may communicate with each other by transmitting and receiving clock signals and data. The semiconductor apparatuses may operate in synchronization with the clock signal, and transmit the data in synchronization with the clock signal or receive the data in synchronization with the clock signal.

The semiconductor apparatuses may each include a receiver circuit to receive the clock signal and the data. In general, the receiver circuit may include an amplifier for amplifying single-ended signals or differential signals. In order to reduce power consumption, the semiconductor apparatuses may activate the receiver circuit only during a period in which an operation of the receiver circuit is required, and deactivate the receiver circuit during other periods. However, when the receiver circuit is activated or deactivated, an unexpected glitch may occur, so that an abnormal output signal is highly likely to be generated. Particularly, semiconductor apparatuses operating at a high frequency may perform an abnormal operation based on the abnormal output signal.

### SUMMARY

In accordance with an embodiment, a receiver circuit may include a first amplification stage, a second amplification stage, and an enable control circuit. The first amplification stage may be configured to generate a first output signal by differentially amplifying a first input signal and a second input signal when a first enable signal is enabled.

The second amplification stage may be configured to generate a second output signal by amplifying the first output signal when a second enable signal is enabled. The enable control circuit may be configured to generate the first and second enable signals based on an amplification enable signal, and to disable the first enable signal after disabling the second enable signal.

In accordance with an embodiment, a receiver circuit may include a first amplification stage, a second amplification stage, a third amplification stage, and an enable control circuit. The first amplification stage may be configured to generate a first output signal by amplifying an input signal pair. The second amplification stage may be configured to generate a second output signal by amplifying the first output signal. The third amplification stage may be configured to generate a third output signal by amplifying the second output signal. The enable control circuit may be configured to sequentially activate the first, second, and third amplification stages and to sequentially deactivate the third, second, and first amplification stages in reverse order to the order in which the first to third amplification stages were activated. In accordance with an embodiment, a receiver circuit may

include a plurality of amplification stages configured sequentially so that the first amplification stage of the plurality of amplification stages receives an input signal and amplifies the input signal to produce an output signal, wherein each subsequent amplification stage of the plurality of amplification stages is configured to amplify the output signal of the previous amplification stage. The receiver circuit may also include an enable control circuit configured to generate a different enable signal to enable each amplification stage of the plurality of amplification stages in a sequential order beginning with the first amplification stage, and to disable the amplification stages in the reverse sequential order beginning with the last amplification stage of the plurality of amplification stages to be enabled.

In accordance with an embodiment, a semiconductor integrated circuit may include an enable control circuit configured to generate a plurality of enable signals that are sequentially enabled. The semiconductor integrated circuit may also include a plurality of amplification stages connected in series, the plurality of amplification stages configured to receive the plurality of enable signals, respectively, and sequentially activate and deactivate based on the plurality of enable signals.

### BRIEF DESCRIPTION OF THE DRAWINGS

FIG. 1 is a diagram illustrating a configuration of an amplifier in accordance with an embodiment.

FIG. 2A is a timing diagram illustrating an operation of the amplifier of FIG. 1.

FIG. 2B is a timing diagram illustrating another operation of the amplifier of FIG. 1.

FIG. 3 is a diagram illustrating a configuration of a receiver circuit in accordance with an embodiment.

FIG. 4 is a diagram illustrating a configuration of a receiver circuit in accordance with an embodiment.

FIG. 5 is a diagram illustrating a configuration of an enable control circuit illustrated in FIG. 4.

FIG. 6 is a timing diagram illustrating an operation of the enable control circuit illustrated in FIG. 5.

FIG. 7 is a timing diagram illustrating an operation of a receiver circuit in accordance with an embodiment.

FIG. 8 is a diagram illustrating a configuration of a semiconductor system in accordance with an embodiment.

### DETAILED DESCRIPTION

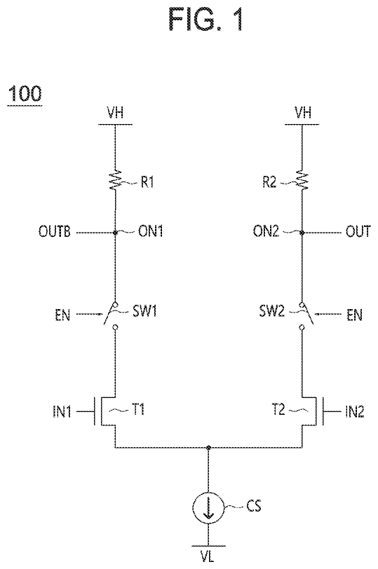

FIG. 1 is a diagram illustrating a configuration of an amplifier 100 in accordance with an embodiment of the present disclosure. Referring to FIG. 1, the amplifier 100 may be a differential amplifier that receives two input signals and generates one output signal or two output signals. The amplifier 100 may receive a first input signal IN1 and a second input signal IN2 and generate an output signal OUT and a complementary output signal OUTB. The amplifier 100 may perform an amplification operation by receiving a first voltage VH and a second voltage VL. The first voltage VH may have a higher voltage level than the second voltage VL. The amplifier 100 may change the voltage levels of the output signal OUT and the complementary output signal OUTB according to the voltage levels of the first and second input signals IN1 and IN2. When the voltage level of the first input signal IN1 is higher than the voltage level of the second input signal IN2, the amplifier 100 may generate the output signal OUT having a higher voltage level than the complementary output signal OUTB. When the voltage level of the first input signal IN1 is lower than the voltage level of the second input signal IN2, the amplifier 100 may generate the output signal OUT having a voltage level lower than the complementary output signal OUTB. The amplifier 100 may further receive an enable signal EN. The amplifier 100 may be activated based on the enable signal EN. The amplifier 100 may be activated when the enable signal EN is enabled, and may be deactivated when the enable signal EN is disabled.

The amplifier 100 may include a first transistor T1, a second transistor T2, a current source CS, a first switch SW1, a second switch SW2, a first resistor R1, and a second resistor R2. The first transistor T1 and the second transistor T2 may be N-channel MOS transistors. A gate of the first transistor T1 may receive the first input signal IN1, and a source of the first transistor T1 may be connected to the current source CS. A gate of the second transistor T2 may receive the second input signal IN2, and a source of the second transistor T2 may be connected to the source of the first transistor T1 and the current source CS. One end of the current source CS may be connected in common to the sources of the first and second transistors T1 and T2, and the other end of the current source CS may be connected to a terminal to which the second voltage VL is supplied. The current source CS may cause current to flow or provide a current path from the sources of the first and second transistors T1 and T2 to the terminal to which the second voltage VL is supplied. One end of the first switch SW1 may be connected to a drain of the first transistor T1, and the other end of the first switch SW1 may be connected to a first output node ON1. The complementary output signal OUTB may be outputted from the first output node ON1. The first switch SW1 may receive the enable signal EN as a control signal, and the switch may be opened or closed between the first transistor T1 and the first output node ON1 based on the enable signal EN. One end of the second switch SW2 may be connected to a drain of the second transistor T2, and the other end of the second switch SW2 may be connected to a second output node ON2. The output signal OUT may be outputted from the second output node ON2. The second switch SW2 may receive the enable signal EN as a control signal, and the switch may be opened or closed between the second transistor T2 and the second output node ON2 based on the enable signal EN. One end of the first resistor R1 may be connected to the first output node ON1, and the other end of the first resistor R1 may be connected to a terminal to which the first voltage VH is supplied. One end of the second resistor R2 may be connected to the second output node ON2, and the other end of the second resistor R2 may be connected to the terminal to which the first voltage VH is supplied.

When the enable signal EN is enabled, as the first and second switches SW1 and SW2 are turned on (closed) and a current path from the terminal to which the first voltage VH is supplied to the terminal to which the second voltage VL is supplied is formed, the amplifier 100 may be activated. When the amplifier 100 is activated, the amplifier 100 may generate the output signal OUT and the complementary output signal OUTB by differentially amplifying the voltage levels of the first and second input signals IN1 and IN2. When the enable signal EN is disabled, as the first and second switches SW1 and SW2 are turned off (opened) and the current path from the terminal to which the first voltage VH is supplied to the terminal to which the second voltage VL is supplied is blocked, the amplifier 100 may be deactivated. FIG. 1 illustrates that the amplifier 100 is an N-type amplifier including an N-channel MOS transistor; however, the amplifier 100 may be replaced with a P-type amplifier. The P-type amplifier may include a P-channel MOS transistor that receives the first and second input signals IN1 and IN2.

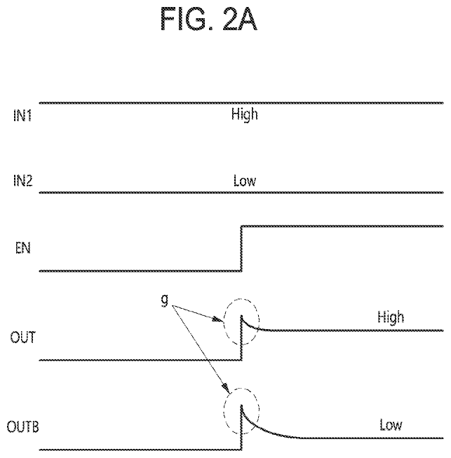

FIG. 2A is a timing diagram illustrating the operation of the amplifier 100 illustrated in FIG. 1. Referring to FIGS. 1 and 2A, the enable signal EN may remain disabled to a low logic level and then be enabled to a high logic level. In such a case, it is assumed that the first input signal IN has a voltage level corresponding to a high logic level and the second input signal IN2 has a voltage level corresponding to a low logic level. When the enable signal EN is enabled, the first and second switches SW1 and SW2 are turned on (closed), and the first voltage VH starts to be supplied from the terminal to which the first voltage VH is supplied to the first and second output nodes ON1 and ON2. When the enable signal EN is enabled, the first and second output nodes ON1 and ON2 may be instantaneously charged at the same time and then the voltage levels of the first and second output nodes ON1 and ON2 may be stabilized to a direct current level DC level according to the voltage levels of the first and second input signals IN1 and IN2. Because the amount of current flowing through the first transistor T1 is greater than the amount of current flowing through the second transistor T2, the complementary output signal OUTB of the first output node ON1 may be stabilized to a low logic level and the output signal OUT of the second output node ON2 may be stabilized to a high logic level. However, at the time when the enable signal EN is enabled, as the first and second output nodes ON1 and ON2 are charged simultaneously and the voltage levels of the output signal OUT and the complementary output signal OUTB are inverted, an abnormal glitch g may occur in the output signal OUT and the complementary output signal OUTB. The abnormal glitch may affect an operation of an internal circuit arranged after the amplifier 100, thereby causing an abnormal operation of the internal circuit.

FIG. 2B is a timing diagram illustrating another operation of the amplifier 100 illustrated in FIG. 1. Referring to FIGS. 1 and 2B, the enable signal EN may remain enabled to a high logic level and then be disabled to a low logic level. In such a case, it is assumed that the first input signal IN1 has a voltage level corresponding to a high logic level and the second input signal IN2 has a voltage level corresponding to a low logic level. When the enable signal EN is disabled, the first and second switches SW1 and SW2 may be turned off (opened) and the supply of the first voltage VH from the terminal to which the first voltage VH is supplied to the first and second output nodes ON1 and ON2 may be blocked. When the enable signal EN is disabled, the first and second output nodes ON1 and ON2 may be simultaneously floated. Accordingly, as the voltage levels of the first and second output nodes ON1 and ON2 are instantaneously discharged, the voltage level of the complementary output signal OUTB and the voltage levels of the output signal OUT may decrease. At the time when the enable signal EN is disabled, as the first and second output nodes ON1 and ON2 are simultaneously discharged and the voltage levels of the first and second output nodes ON1 and ON2 are inverted, an abnormal glitch g′ may occur in the output signal OUT and the complementary output signal OUTB. The abnormal glitch may affect an operation of an internal circuit arranged after the amplifier 100, thereby causing an abnormal operation of the internal circuit.

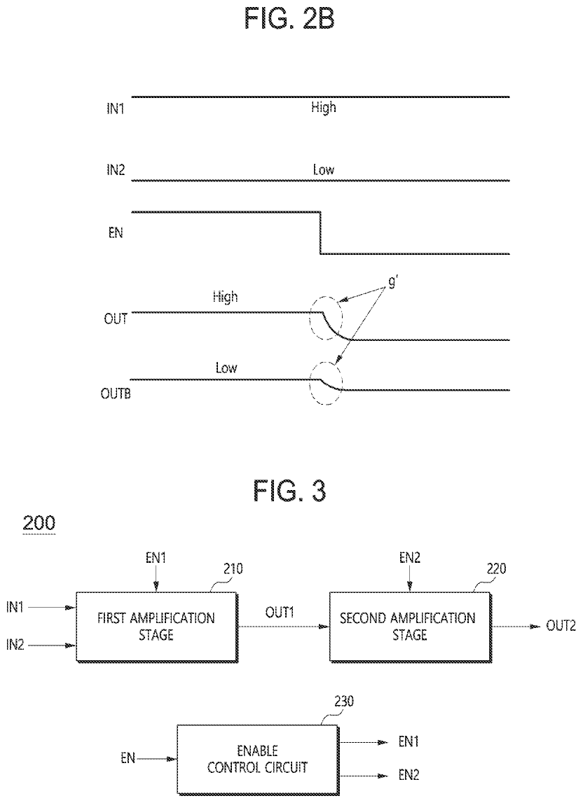

FIG. 3 is a diagram illustrating a configuration of a receiver circuit 200 in accordance with an embodiment of the present disclosure. Referring to FIG. 3, the receiver circuit 200 may receive an input signal pair and generate an output signal. The input signal pair may include a first input signal IN1 and a second input signal IN2. The second input signal IN2 may be a complementary signal of the first input signal IN1, and the first and second input signals IN1 and IN2 may be a differential signal pair. In an embodiment, the first input signal IN1 may be a single-ended signal and the second input signal IN2 may be a reference voltage. The reference voltage may have a voltage level corresponding to the middle of a range in which the first input signal IN1 swings. The receiver circuit 200 may include a plurality of amplification stages. The receiver circuit 200 may generate the output signal by amplifying the first and second input signals IN1 and IN2 through the plurality of amplification stages. The receiver circuit 200 may differently set the timings at which the plurality of amplification stages are deactivated. The receiver circuit 200 may control the plurality of amplification stages to be sequentially disabled. The receiver circuit 200 may also differently set the timings at which the plurality of amplification stages are enabled. The receiver circuit 200 may control the plurality of amplification stages to be sequentially enabled. The enablement and disablement of the plurality of amplification stages, for example, are staggered in time.

The receiver circuit 200 may include a first amplification stage 210 and a second amplification stage 220 sequentially connected in series. The first amplification stage 210 may receive the first and second input signals IN1 and IN2, and generate a first output signal OUT1 by differentially amplifying the first and second input signals IN1 and IN2. The second amplification stage 220 may receive the first output signal OUT1 and generate a second output signal OUT2 by amplifying the first output signal OUT1. The first and second amplification stages 210 and 220 may each include at least one amplifier. In an embodiment, the first amplification stage 210 may generate a complementary signal of the first output signal together with the first output signal OUT1, and the second amplification stage 220 may generate the second output signal OUT2 by differentially amplifying the output signal OUT1 and the complementary signal of the first output signal. In an embodiment, the second amplification stage 220 may generate a complementary signal of the second output signal together with the second output signal OUT2.

The first amplification stage 210 may receive a first enable signal EN1, and the second amplification stage 220 may receive a second enable signal EN2. The first amplification stage 210 may be activated based on the first enable signal EN1. When the first enable signal EN1 is enabled, the first amplification stage 210 may be activated, and when the first enable signal EN1 is disabled, the first amplification stage 210 may be deactivated. The second amplification stage 220 may be activated based on the second enable signal EN2. When the second enable signal EN2 is enabled, the second amplification stage 220 may be activated, and when the second enable signal EN2 is disabled, the second amplification stage 220 may be deactivated. The receiver circuit 200 may sequentially disable the first and second amplification stages 210 and 220. The receiver circuit 200 may disable the second enable signal EN2 and then disable the first enable signal EN1. The receiver circuit 200 may sequentially enable the first and second amplification stages 210 and 220. The order in which the first and second amplification stages 210 and 220 are enabled may be opposite to the order in which the first and second amplification stages 210 and 220 are disabled. The receiver circuit 200 may enable the first enable signal EN1 and then enable the second enable signal EN2. Accordingly, in a period during which the receiver circuit 200 operates, the first amplification stage 210 may be activated before the second amplification stage 220 and deactivated later than the second amplification stage 220.

The receiver circuit 200 may further include an enable control circuit 230. The enable control circuit 230 may receive an amplification enable signal EN, and generate the first and second enable signals EN1 and EN2 based on the amplification enable signal EN. The amplification enable signal EN may be a signal that defines an operation period of the receiver circuit 200. When the amplification enable signal EN is enabled, the enable control circuit 230 may first enable the first enable signal EN1, and then enable the second enable signal EN2. When the amplification enable signal EN is disabled, the enable control circuit 230 may first disable the second enable signal EN2, and then disable the first enable signal EN1.

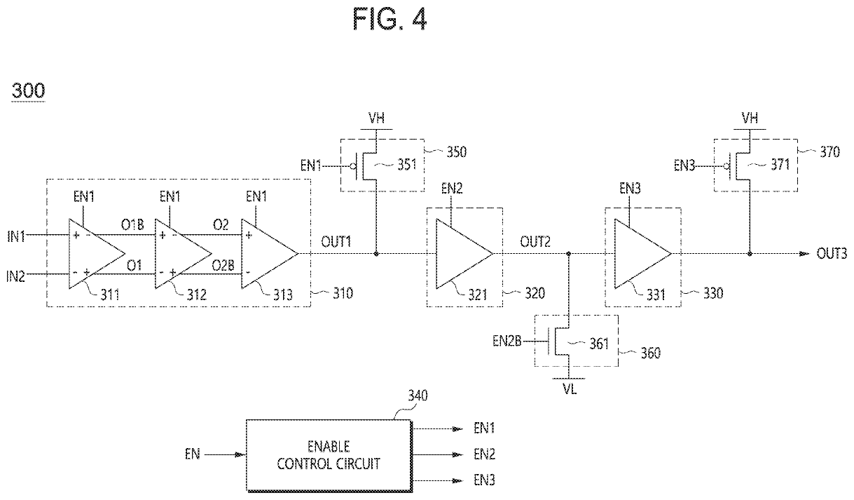

FIG. 4 is a diagram illustrating a configuration of a receiver circuit 300 in accordance with an embodiment of the present disclosure. Referring to FIG. 4, the receiver circuit 300 may include a first amplification stage 310, a second amplification stage 320, a third amplification stage 330, and an enable control circuit 340. For some embodiments, a plurality of amplification stages and an enable control circuit may be embodied by a semiconductor integrated circuit. The first amplification stage 310 may receive a first input signal IN1 and a second input signal IN2, and generate a first output signal OUT1 by differentially amplifying the first and second input signals IN1 and IN2. The first amplification stage 310 may receive a first enable signal EN1 and be activated based on the first enable signal EN1. When the first enable signal EN1 is enabled, the first amplification stage 310 may be activated. When the first enable signal EN1 is disabled, the first amplification stage 310 may be deactivated.

The second amplification stage 320 may be connected in cascade to the next stage of the first amplification stage 310. For example, the first amplification stage 310 and the second amplification stage 320 may be electrically coupled in series. The second amplification stage 320 may receive the first output signal OUT1 and generate a second output signal OUT2 by amplifying the first output signal OUT1. The second amplification stage 320 may receive the second enable signal EN2 and be activated based on the second enable signal EN2. When the second enable signal EN2 is enabled, the second amplification stage 320 may be activated. When the second enable signal EN2 is disabled, the second amplification stage 320 may be deactivated. In an embodiment, the first amplification stage 310 may generate the first output signal OUT1 and a complementary signal of the first output signal, and the second amplification stage 320 may generate the second output signal OUT2 by differentially amplifying the first output signal OUT1 and the complementary signal of the first output signal.

The third amplification stage 330 may be connected in cascade to the next stage of the second amplification stage 320. For example, the second amplification stage 320 and the third amplification stage 330 may be electrically coupled in series. The third amplification stage 330 may receive the second output signal OUT2, and generate a third output signal OUT3 by amplifying the second output signal OUT2. The third amplification stage 330 may receive a third enable signal EN3 and be activated based on the third enable signal EN3. When the third enable signal EN3 is enabled, the third amplification stage 330 may be activated. When the third enable signal EN3 is disabled, the third amplification stage 330 may be deactivated. In an embodiment, the second amplification stage 320 may generate the second output signal OUT2 and a complementary signal of the second output signal, and the third amplification stage 330 may generate the third output signal OUT3 by differentially amplifying the second output signal OUT2 and the complementary signal of the second output signal. The third amplification stage 330 may also generate the third output signal OUT3 and a complementary signal of the third output signal.

The enable control circuit 340 may activate the first to third amplification stages 310, 320, and 330 during an operation period of the receiver circuit 300. When the operation period of the receiver circuit 300 starts, the enable control circuit 340 may activate the first to third amplification stages 310, 320, and 330. When the operation period of the receiver circuit 300 ends, the enable control circuit 340 may sequentially deactivate the activated first and third amplification stages 310, 320, and 330. The enable control circuit 340 may sequentially deactivate the third, second, and first amplification stages 330, 320, and 310. The enable control circuit 340 may first deactivate the third amplification stage 330, deactivate the second amplification stage 320, and then deactivate the first amplification stage 310. The enable control circuit 340 may sequentially activate the first to third amplification stages 310, 320, and 330 in the reverse order of the order in which the first to third amplification stages 310, 320, and 330 are deactivated. The enable control circuit 340 may first activate the first amplification stage 310, activate the second amplification stage 320, and then the third amplification stage 330.

The enable control circuit 340 may receive an amplification enable signal EN, and generate the first enable signal EN1, the second enable signal EN2, and the third enable signal EN3 based on the amplification enable signal EN. In an embodiment, the enable control circuit 340 may also generate and output a complementary signal EN2B of the second enable signal EN2. The amplification enable signal EN may be a signal that defines an operation period of the receiver circuit 300. When the amplification enable signal EN is enabled, the receiver circuit 300 may be activated and may receive the first and second input signals IN1 and IN2. When the amplification enable signal EN is disabled, the receiver circuit 300 may be deactivated and might not receive the first and second input signals IN1 and IN2. When the amplification enable signal EN is enabled, the enable control circuit 340 may first enable the first enable signal EN1 and then enable the second enable signal EN2. The enable control circuit 340 may enable the second enable signal EN2 and then enable the third enable signal EN3. When the amplification enable signal EN is disabled, the enable control circuit 340 may first disable the third enable signal EN3 and then disable the second enable signal EN2. The enable control circuit 340 may disable the second enable signal EN2 and then disable the first enable signal EN1.

The first amplification stage 310 may include at least one amplifier. The first amplification stage 310 may include a first amplifier 311, a second amplifier 312, and a third amplifier 313. The first to third amplifiers 311 to 313 may all be differential amplifiers. The first to third amplifiers 311 to 313 may operate by receiving the first voltage VH and the second voltage VL. The first amplifier 311 may receive the first input signal IN1 and the second input signal IN2, and generate a first intermediate output signal pair by differentially amplifying the first and second input signals IN1 and IN2. The first intermediate output signal pair may include a first intermediate output signal O1 and a complementary signal O1B of the first intermediate output signal O1. The second amplifier 312 may receive the first intermediate output signal O1 and the complementary signal O1B of the first intermediate output signal O1, and generate a second intermediate output signal pair by differentially amplifying the first intermediate output signal O1 and the complementary signal O1B of the first intermediate output signal O1. The second intermediate output signal pair may include a second intermediate output signal O2 and a complementary signal O2B of the second intermediate output signal O2. The third amplifier may receive the second intermediate output signal O2 and the complementary signal O2B of the second intermediate output signal O2, and generate the first output signal OUT1 by differentially amplifying the second intermediate output signal O2 and the complementary signal O2B of the second intermediate output signal O2. The first to third amplifiers 311 to 313 may each have the same or similar configuration as the amplifier illustrated in FIG. 1. The first to third amplifiers 311 to 313 may receive the first enable signal EN1 in common. When the first enable signal EN1 is enabled, the first to third amplifiers 311 to 313 may be activated. When the first enable signal EN1 is disabled, the first to third amplifiers 311 to 313 may be deactivated.

The second amplification stage 320 may include at least one amplifier. The second amplification stage 320 may include a fourth amplifier 321. The fourth amplifier 321 may include at least one of an inverter and an inverting amplifier. In an embodiment, the fourth amplifier 321 may also include a buffer or a single stage amplifier such as a common-source amplifier, a source-follower amplifier, a common-gate amplifier, or a cascode amplifier. The fourth amplifier 321 may operate by receiving the first voltage VH and the second voltage VL. The fourth amplifier 321 may receive the first output signal OUT1, and generate the second output signal OUT2 by inverting and amplifying the first output signal OUT1. The second output signal OUT2 may have a voltage level opposite to that of the first output signal OUT1. The fourth amplifier 321 may receive the second enable signal EN2. When the second enable signal EN2 is enabled, the fourth amplifier 321 may be activated. When the second enable signal EN2 is disabled, the fourth amplifier 321 may be deactivated.

The third amplification stage 330 may include at least one amplifier. The third amplification stage 330 may include a fifth amplifier 331. The fifth amplifier 331 may include at least one of an inverter and an inverting amplifier. In an embodiment, the fifth amplifier 331 may also include a buffer or a single stage amplifier such as a common-source amplifier, a source-follower amplifier, a common-gate amplifier, or a cascode amplifier. The fifth amplifier 331 may operate by receiving the first voltage VH and the second voltage VL. The fifth amplifier 331 may receive the second output signal OUT2, and generate the third output signal OUT3 by inverting and amplifying the second output signal OUT2. The third output signal OUT3 may have a voltage level opposite to that of the second output signal OUT2. The fifth amplifier 331 may receive the third enable signal EN3. When the third enable signal EN3 is enabled, the fifth amplifier 331 may be activated. When the third enable signal EN3 is disabled, the fifth amplifier 331 may be deactivated.

The receiver circuit 300 may further include a first precharge circuit 350. The first precharge circuit 350 may receive the first enable signal EN1, and precharge the first output signal OUT1 to the voltage level of the first voltage VH based on the first enable signal EN1. When the first enable signal EN1 is disabled and the first amplification stage 310 is deactivated, the first precharge circuit 350 may fix the first output signal OUT1 to the voltage level of the first voltage VH. The receiver circuit 300 may further include a discharge circuit 360. The discharge circuit 360 may discharge the second output signal OUT2 to the voltage level of the second voltage VL based on the second enable signal EN2. The discharge circuit 360 may receive a complementary signal EN2B of the second enable signal EN2, and discharge the second output signal OUT2 to the voltage level of the second voltage VL in response to the complementary signal EN2B of the second enable signal EN2. When the second enable signal EN2 is disabled and the second amplification stage 320 is deactivated, the discharge circuit 360 may fix the second output signal OUT2 to the voltage level of the second voltage VL. The receiver circuit 300 may further include a second precharge circuit 370. The second precharge circuit 370 may receive the third enable signal EN3, and precharge the third output signal OUT3 to the voltage level of the first voltage VH based on the third enable signal EN3. When the third enable signal EN3 is disabled and the third amplification stage 330 is deactivated, the second precharge circuit 370 may fix the third output signal OUT3 to the voltage level of the first voltage VH.

The first precharge circuit 350 may include a first transistor 351. The first transistor 351 may be a P-channel MOS transistor. A gate of the first transistor 351 may receive the first enable signal EN1, a source of the first transistor 351 may receive the first voltage VH, and a drain of the first transistor 351 may be connected to the first output signal OUT1. The discharge circuit 360 may include a second transistor 361. The second transistor 361 may be an N-channel MOS transistor. A gate of the second transistor 361 may receive the complementary signal EN2B of the second enable signal EN2, a drain of the second transistor 361 may be connected to the second output signal OUT2, and a source of the second transistor 361 may receive the second voltage VL. The second precharge circuit 370 may include a third transistor 371. The third transistor 371 may be a P-channel MOS transistor. A gate of the third transistor 371 may receive the third enable signal EN3, a source of the third transistor 371 may receive the first voltage VH, and a drain of the third transistor 371 may be connected to the third output signal OUT3.

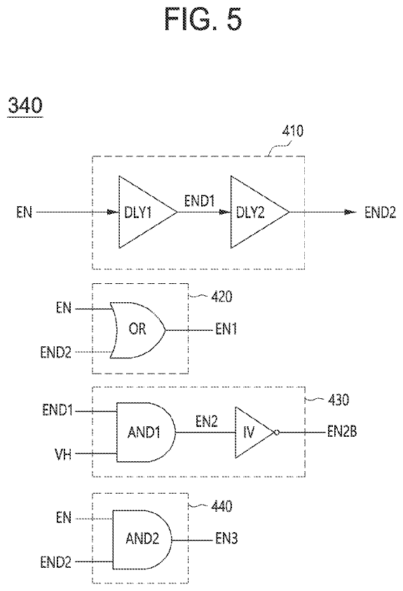

FIG. 5 is a diagram illustrating a configuration of the enable control circuit 340 illustrated in FIG. 4. Referring to FIG. 5, the enable control circuit 340 may include a delay circuit 410, a first gating circuit 420, a second gating circuit 430, and a third gating circuit 440. The delay circuit 410 may receive the amplification enable signal EN, and generate a first delay signal END1 and a second delay signal END2 by sequentially delaying the amplification enable signal EN. The delay circuit 410 may generate the first delay signal END1 by delaying the amplification enable signal EN by a unit delay time, and generate the second delay signal END2 by delaying the first delay signal END1 by the unit delay time. The unit delay time may be a delay time that is arbitrarily set. For example, the unit delay time may correspond to a minimum time required for the voltage level of the first output signal OUT1 to stabilize from the time when the first amplification stage 310 is activated or deactivated. Alternatively, the unit delay time may correspond to a minimum time required for an abnormal glitch occurring in the first output signal OUT1 to disappear as the first amplification stage 310 is activated or deactivated. The delay circuit 410 may include a first delay DLY1 and a second delay DLY2. The delay times of the first delay DLY1 and the second delay DLY2 may be substantially equal to the unit delay time. The first delay DLY1 may receive the amplification enable signal EN, and generate the first delay signal END1 by delaying the amplification enable signal EN. The second delay DLY2 may receive the first delay signal END1, and generate the second delay signal END2 by delaying the first delay signal END1.

The first gating circuit 420 may receive the amplification enable signal EN and the second delay signal END2. The first gating circuit 420 may generate the first enable signal EN1 based on the amplification enable signal EN and the second delay signal END2. When at least one of the amplification enable signal EN and the second delay signal END2 is enabled, the first gating circuit 420 may enable the first enable signal EN1. When both the amplification enable signal EN and the second delay signal END2 are disabled, the first gating circuit 420 may disable the first enable signal EN1. When the amplification enable signal EN is enabled, the first gating circuit 420 may enable the first enable signal EN1, and when the second delay signal END2 is disabled, the first gating circuit 420 may disable the first enable signal EN1. The first gating circuit 420 may include an OR gate OR. A first input terminal of the OR gate OR may receive the amplification enable signal EN, a second input terminal of the OR gate OR may receive the second delay signal END2, and the first enable signal EN1 may be outputted from an output terminal of the OR gate OR.

The second gating circuit 430 may receive the first delay signal END1. The second gating circuit 430 may provide the first delay signal END1 as the second enable signal EN2. When the first delay signal END1 is enabled, the second gating circuit 430 may enable the second enable signal EN2, and when the first delay signal END1 is disabled, the second gating circuit 430 may disable the second enable signal EN2. The second gating circuit 430 may include a first AND gate AND1 and an inverter IV. A first input terminal of the first AND gate AND1 may receive the first delay signal END1, a second input terminal of the first AND gate AND1 may receive the first voltage VH, and the second enable signal EN2 may be outputted from an output terminal of the first AND gate AND1. An input terminal of the inverter IV may receive the second enable signal EN2, and the complementary signal EN2B of the second enable signal EN2 may be outputted from an output terminal of the inverter IV.

The third gating circuit 440 may receive the amplification enable signal EN and the second delay signal END2. The third gating circuit 440 may generate the third enable signal EN3 based on the amplification enable signal EN and the second delay signal END2. When both the amplification enable signal EN and the second delay signal END2 are enabled, the third gating circuit 440 may enable the third enable signal EN3. When at least one of the amplification enable signal EN and the second delay signal END2 is disabled, the third gating circuit 440 may disable the third enable signal EN3. When the second delay signal END2 is enabled, the third gating circuit 440 may enable the third enable signal EN3, and when the amplification enable signal EN is disabled, the third gating circuit 440 may disable the third enable signal EN3. The third gating circuit 440 may include a second AND gate AND2. A first input terminal of the second AND gate AND2 may receive the amplification enable signal EN, a second input terminal of the second AND gate AND2 may receive the second delay signal END2, and the third enable signal EN3 may be outputted from an output terminal of the second AND gate AND2.

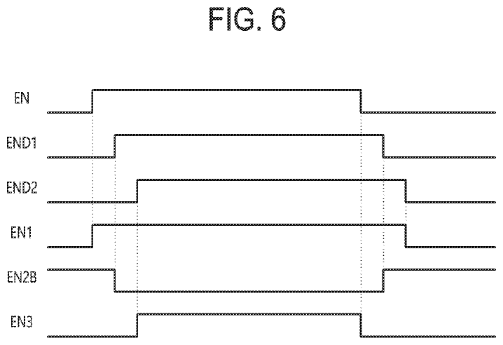

FIG. 6 is a timing diagram illustrating the operation of the enable control circuit 340 illustrated in FIG. 5. Referring to FIGS. 5 and 6, the delay circuit 410 may generate the first delay signal END1 and the second delay signal END2 by sequentially delaying the amplification enable signal EN. The amplification enable signal EN may be first enabled, and then the first and second delay signals END1 and END2 may be sequentially enabled. The first gating circuit 420 may enable the first enable signal EN1 to a high logic level at the time when the amplification enable signal EN is enabled. When the first delay signal END1 is enabled to a high logic level, the second gating circuit 430 may enable the second enable signal EN2 to a high logic level. When the second delay signal END2 is enabled to a high logic level, the third gating circuit 440 may enable the third enable signal EN3 to a high logic level. When the amplification enable signal EN is disabled to a low logic level, the delay circuit 410 may sequentially disable the first and second delay signals END1 and END2 to a low logic level. At the time when the amplification enable signal EN is disabled, the third gating circuit 440 may disable the third enable signal EN3 to a low logic level. When the first delay signal END1 is disabled, the second gating circuit 430 may disable the second enable signal EN2 to a low logic level. When the second delay signal END2 is disabled, the first gating circuit 420 may disable the first enable signal EN1 to a low logic level. Accordingly, the first enable signal EN1 may be first enabled, and then the second and third enable signals EN2 and EN3 may be sequentially enabled. In contrast, the third enable signal EN3 may be first disabled, and then the second and first enable signals EN2 and EN1 may be sequentially disabled. The enable period of the first enable signal EN1 may be the longest, the enable period of the second enable signal EN2 may be shorter than the enable period of the first enable signal EN1, and the enable period of the third enable signal EN3 may be the shortest. In this way, the order of enablement is EN1 is enabled first, then EN2, and then EN3. The order of disablement is reversed, namely, EN3 is disabled first, then EN2, and then EN1.

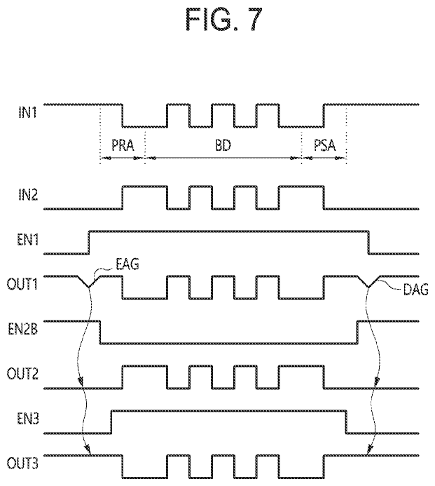

FIG. 7 is a timing diagram illustrating the operation of the receiver circuit 300 in accordance with an embodiment of the present disclosure. The operation of the receiver circuit 300 is described below with reference to FIGS. 4, 6, and 7. When the amplification enable signal EN is in a disabled state, the first precharge circuit 350 may precharge the first output signal OUT1 to a high logic level, the discharge circuit 360 may discharge the second output signal OUT2 to a low logic level, and the second precharge circuit 370 may precharge the third output signal OUT3 to a high logic level. The amplification enable signal EN may be enabled so that a period during which the first input signal IN1 and the second input signal IN2 are input may be covered. When the amplification enable signal EN is enabled, the first enable signal EN1 may be enabled, the first precharge circuit 350 may be turned off, and the first amplification stage 310 may be activated. After the first enable signal EN1 is enabled, the second and third enable signals EN2 and EN3 may be sequentially enabled. When the second and third enable signals EN2 and EN3 are enabled, the discharge circuit 360 and the second precharge circuit 370 may be turned off, and the second amplification stage 320 and the third amplification stage 330 may be sequentially activated. After the first to third enable signals EN1 to EN3 are enabled, preambles PRA, bodies BD, and postambles PSA of the first input signal IN1 and the second input signal IN2 may be sequentially inputted. By differentially amplifying the first and second input signals IN1 and IN2, the first amplification stage 310 may generate the first output signal OUT1 that changes substantially the same as the first input signal IN1. By amplifying the first output signal OUT1, the second amplification stage 320 may generate the second output signal OUT2 that changes complementarily to the first output signal OUT1. The third amplification stage 330 may amplify the second output signal OUT2 and generate the third output signal OUT3 that changes complementarily to the second output signal OUT2. After the postambles PSA of the first and second input signals IN1 and IN2 are transmitted, the amplification enable signal EN may be disabled. When the amplification enable signal EN is disabled, the third enable signal EN3 may be first disabled and the third amplification stage 330 may be deactivated. The second precharge circuit 370 may precharge the voltage level of the third output signal OUT3 to the voltage level of the first voltage VH. After the third enable signal EN3 is disabled, the second and first enable signals EN2 and EN1 may be sequentially disabled. When the second and first enable signals EN2 and EN1 are disabled, the second and first amplification stages 320 and 310 may be sequentially deactivated. The discharge circuit 360 may discharge the second output signal OUT2 to the voltage level of the second voltage VL, and the first precharge circuit 350 may precharge the first output signal OUT1 to the voltage level of the first voltage VH.

When the first enable signal EN1 is enabled, output nodes of the first to third amplifiers 311 to 313 constituting the first amplification stage 310 may be simultaneously charged, and an abnormal glitch EAG may occur in the first output signal OUT1. Because the second and third enable signals EN2 and EN3 are enabled later than the first enable signal EN1, even though the second amplification stage 320 and the third amplification stage 330 are activated, the second and third enable signals EN2 and EN3 might not be affected by the abnormal glitch EAG. In other words, the second amplification stage 320 might not amplify the abnormal glitch EAG and the voltage levels of the second output signal OUT2 and the third output signal OUT3 might not be affected. When the first enable signal EN1 is disabled, the output nodes of the first to third amplifiers 311 to 313 constituting the first amplification stage 310 may be simultaneously discharged, and an abnormal glitch DAG may occur in the first output signal OUT1. Because the second and third enable signals EN2 and EN3 are in a disabled state before the first enable signal EN1 and the second and third amplification stages 320 and 330 are also in a deactivated state, the abnormal glitch DAG of the first output signal OUT1 might not affect the voltage levels of the second and third output signals OUT2 and OUT3.

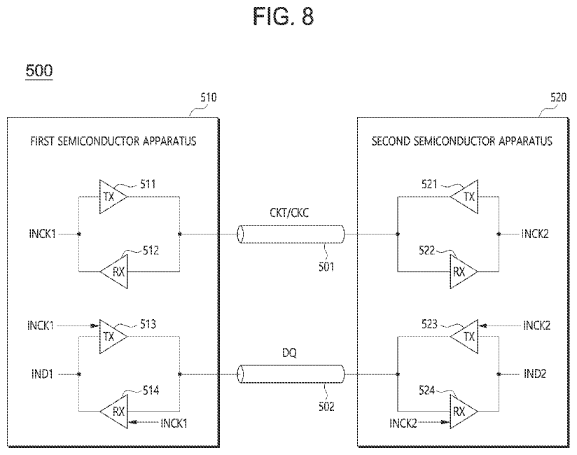

FIG. 8 is a diagram illustrating a configuration of a semiconductor system 500 in accordance with an embodiment of the present disclosure. Referring to FIG. 8, the semiconductor system 500 may include a first semiconductor apparatus 510 and a second semiconductor apparatus 520. The first semiconductor apparatus 510 may be a master device that provides various control signals required for the second semiconductor apparatus 520 to operate. The second semiconductor apparatus 520 may be a slave device that performs various operations under the control of the first semiconductor apparatus 510. The first semiconductor apparatus 510 may include various types of host devices. For example, the first semiconductor apparatus 510 may include a central processing unit (CPU), a graphics processing unit (GPU), a multimedia processor (MMP), and a digital signal processor, an application processor (AP), a memory controller, and the like. For example, the second semiconductor apparatus 520 may be a memory apparatus, and the memory apparatus may include volatile memory and non-volatile memory. The volatile memory may include static RAM (SRAM), dynamic RAM (DRAM), and synchronous DRAM (SDRAM). The non-volatile memory may include read only memory (ROM), programmable ROM (PROM), electrically erasable programmable ROM (EEPROM), erasable PROM (EPROM), flash memory, phase change RAM (PRAM), magnetic RAM (MRAM), resistive RAM (RRAM), ferroelectric RAM (FRAM), and the like.

The second semiconductor apparatus 520 may be connected to the first semiconductor apparatus 110 through a plurality of buses. The plurality of buses may be signal transmission paths, links, or channels for transmitting signals. The plurality of buses may include a clock bus 501 and a data bus 502. The clock bus 501 and the data bus 502 may be bidirectional buses. The second semiconductor apparatus 520 may be connected to the first semiconductor apparatus 510 through the clock bus 501, and may transmit a clock signal pair CKT/CKC to the first semiconductor apparatus 510 or receive the clock signal pair CKT/CKC transmitted from the first semiconductor apparatus 510, through the clock bus 501. The second semiconductor apparatus 520 may be connected to the first semiconductor apparatus 510 through the data bus 502, and may transmit data DQ to the first semiconductor apparatus 510 or receive the data DQ transmitted from the first semiconductor apparatus 510, through the data bus 502. The clock signal pair CKT/CKC may be synchronized with the data DQ, and the data DQ may be aligned with an edge of the clock signal pair CKT/CKC and transmitted through the data bus 501. In an embodiment, the clock bus 501 may be a data strobe bus, and the clock signal pair CKT/CKC may be a data strobe signal pair.

The first semiconductor apparatus 510 may include a clock transmitter 511, a clock receiver 512, a data transmitter 513, and a data receiver 514. The clock transmitter 511 may generate the clock signal pair CKT/CKC based on an internal clock signal INCK1 of the first semiconductor apparatus 510, and transmit the clock signal pair CKT/CKC to the second semiconductor apparatus 520 through the clock bus 501. The clock receiver 512 may receive the clock signal pair CKT/CKC transmitted from the second semiconductor apparatus 520 through the clock bus 501, and generate the internal clock signal INCK1 of the first semiconductor apparatus 510. Any one of the receiver circuits 200 and 300 respectively illustrated in FIGS. 3 and 4 may be applied as the clock receiver 512. The data transmitter 513 may generate the data DQ from internal data IND1 of the first semiconductor apparatus 510, and transmit the data DQ to the second semiconductor apparatus 520 through the data bus 502. The data transmitter 513 may receive the internal clock signal INCK1 and transmit the data DQ by synchronizing the internal data IND1 with the internal clock signal INCK1. The data receiver 514 may receive the data DQ transmitted from the second semiconductor apparatus 520 through the data bus 502, and generate the internal data IND1 of the first semiconductor apparatus 510. The data receiver 514 may receive the internal clock signal INCK1 and receive the data DQ in synchronization with the internal clock signal INCK1, thereby generating the internal data IND1.

The second semiconductor apparatus 520 may include a clock transmitter 521, a clock receiver 522, a data transmitter 523, and a data receiver 524. The clock transmitter 521 may generate the clock signal pair CKT/CKC based on an internal clock signal INCK2 of the second semiconductor apparatus 520, and transmit the clock signal pair CKT/CKC to the first semiconductor apparatus 510 through the clock bus 501. The clock receiver 522 may receive the clock signal pair CKT/CKC transmitted from the first semiconductor apparatus 510 through the clock bus 501, and generate the internal clock signal INCK2 of the second semiconductor apparatus 520. Any one of the receiver circuits 200 and 300 respectively illustrated in FIGS. 3 and 4 may be applied as the clock receiver 522. The data transmitter 523 may generate the data DQ from internal data IND2 of the second semiconductor apparatus 520, and transmit the data DQ to the first semiconductor apparatus 510 through the data bus 502. The data transmitter 523 may receive the internal clock signal INCK2 and transmit the data DQ by synchronizing the internal data IND2 with the internal clock signal INCK2. The data receiver 524 may receive the data DQ transmitted from the first semiconductor apparatus 510 through the data bus 502, and generate the internal data IND2 of the second semiconductor apparatus 520. The data receiver 524 may receive the internal clock signal INCK2 and receive the data DQ in synchronization with the internal clock signal INCK2, thereby generating the internal data IND2.

A person skilled in the art to which the present disclosure pertains will understand that the present disclosure may be carried out in other specific forms without changing its technical spirit or essential features. Therefore, it should be understood that the embodiments described above are illustrative in all aspects, not limitative. The scope of the present disclosure is defined by the claims described below rather than the detailed description, and it should be construed that all changes or modified forms derived from the meaning and scope of the claims and the equivalent concept thereof are included in the scope of the present disclosure.

What is claimed is:

1. A receiver circuit comprising:
a first amplification stage configured to generate a first output signal by differentially amplifying a first input signal and a second input signal when a first enable signal is enabled;
a second amplification stage configured to generate a second output signal by amplifying the first output signal when a second enable signal is enabled; and
an enable control circuit configured to generate the first and second enable signals based on an amplification enable signal, and to disable the first enable signal after disabling the second enable signal.

2. The receiver circuit according to claim 1, wherein the enable control circuit is configured to enable the second enable signal after enabling the first enable signal.

3. The receiver circuit according to claim 1, wherein the second input signal is a complementary signal of the first input signal.

4. The receiver circuit according to claim 1, wherein the first amplification stage comprises:
a first amplifier configured to output an intermediate output signal pair by differentially amplifying the first and second input signals when the first enable signal is enabled; and
a third amplifier configured to generate the first output signal by differentially amplifying the intermediate output signal pair when the first enable signal is enabled.

5. The receiver circuit according to claim 4, further comprising:
a first precharge circuit configured to precharge the first output signal to a voltage level of a first voltage based on the first enable signal.

6. The receiver circuit according to claim 5, further comprising:
a discharge circuit configured to discharge the second output signal to a voltage level of a second voltage based on the second enable signal.

7. The receiver circuit according to claim 1, further comprising:
a third amplification stage configured to generate a third output signal by amplifying the second output signal when a third enable signal is enabled.

8. The receiver circuit according to claim 7, wherein the enable control circuit is further configured to generate the third enable signal based on the amplification enable signal, enable the third enable signal after enabling the second enable signal, and disable the second enable signal after disabling the third enable signal.

9. The receiver circuit according to claim 7, further comprising:
a second precharge circuit configured to precharge the third output signal to a voltage level of a first voltage based on the third enable signal.

10. A receiver circuit comprising:
a first amplification stage configured to generate a first output signal by amplifying an input signal pair;
a second amplification stage configured to generate a second output signal by amplifying the first output signal;
a third amplification stage configured to generate a third output signal by amplifying the second output signal; and
an enable control circuit configured to sequentially activate the first, second, and third amplification stages and to sequentially deactivate the third, second, and first amplification stages in reverse order to the order in which the first to third amplification stages were activated.

11. The receiver circuit according to claim 10, wherein the enable control circuit is configured to generate a first enable signal, a second enable signal, and a third enable signal based on an amplification enable signal, sequentially enable the first, second, and third enable signals, and sequentially disable the third, second, and first enable signals in reverse order to the order in which the first to third enable signals were enabled.

12. The receiver circuit according to claim 11, wherein the first amplification stage is configured to generate the first output signal by differentially amplifying the input signal pair when the first enable signal is enabled.

13. The receiver circuit according to claim 11, wherein the second amplification stage is configured to generate the second output signal by amplifying the first output signal when the second enable signal is enabled.

14. The receiver circuit according to claim 11, wherein the third amplification stage is configured to generate the third output signal by amplifying the second output signal when the third enable signal is enabled.

15. The receiver circuit according to claim 11, further comprising:
a first precharge circuit configured to precharge the first output signal to a voltage level of a first voltage based on the first enable signal.

16. The receiver circuit according to claim 11, further comprising:
a discharge circuit configured to discharge the second output signal to a voltage level of a second voltage based on the second enable signal.

17. The receiver circuit according to claim 11, further comprising:
a second precharge circuit configured to precharge the third output signal to a voltage level of a first voltage based on the third enable signal.

18. The receiver circuit according to claim 11, wherein the enable control circuit comprises:
a delay circuit configured to generate a first delay signal and a second delay signal by sequentially delaying the amplification enable signal;
a first gating circuit configured to enable the first enable signal when the amplification enable signal is enabled and to disable the first enable signal when the second delay signal is disabled;
a second gating circuit configured to provide the first delay signal as the second enable signal; and
a third gating circuit configured to enable the third enable signal when the second delay enable signal is enabled and to disable the third enable signal when the amplification enable signal is disabled.

19. A semiconductor integrated circuit, comprising:
an enable control circuit configured to generate a plurality of enable signals, and configured to sequentially disable the plurality of enable signals; and
a plurality of amplification stages connected in series, the plurality of amplification stages configured to receive the plurality of enable signals, respectively, and sequentially deactivate based on the plurality of enable signals.
